(19) United States
(12) Patent Application Publication
(10) Pub. No.: US 2026/0237602 A1
(43) Pub. Date: Aug. 13, 2026

(54) SYSTEM AND METHOD FOR A DOUBLE-SIDED ATMOSPHERIC PLASMA HEAD

(71) Applicant: Ontos Equipment Systems, Inc., CHESTER, NH (US)

(72) Inventor: DAVID MEYER, JEFFERSONVILLE, VT (US)

(73) Assignee: Ontos Equipment Systems, Inc., CHESTER, NH (US)

(21) Appl. No.: 19/447,782

(22) Filed: Jan. 13, 2026

Related U.S. Application Data
(60) Provisional application No. 63/744,915, filed on Jan. 14, 2025.

(51) Int. Cl. H01J 37/32; H10W 72/00; H10W 80/00

(52) U.S. Cl. CPC H01J 37/32018; H01J 37/3244; H01J 37/32541; H01J 37/32568; H01J 37/32825; H10W 72/07141; H10W 80/331; H01J 2237/002

(57) ABSTRACT

A double-sided atmospheric pressure plasma head generates two glow discharge-type plasma gases that are directed in opposite directions. A double-sided atmospheric plasma head includes a single plasma source that has two separate internal process gas paths and two separate RF zones that generate two separate plasma gases that exit the plasma head through two separate output slits. The two separate gas paths and the two separate RF zones are coupled to the same single source, thus enabling a single control system to operate the two opposite directed plasmas simultaneously.

### CROSS REFERENCE TO RELATED CO-PENDING APPLICATIONS

This application claims the benefit of U.S. provisional application Ser. No. 63/744,915 filed on Jan. 14, 2025 and entitled “SYSTEM AND METHOD FOR A DOUBLE-SIDED ATMOSPHERIC PLASMA HEAD”, which is commonly assigned and the contents of which are expressly incorporated herein by reference.

### FIELD OF THE INVENTION

The present invention relates to a system and method for a double-sided atmospheric plasma head, and in particular to a double-sided atmospheric plasma source head that provides plasma gases directed in opposite directions.

### BACKGROUND OF THE INVENTION

In wafer-to-wafer and wafer-to-chip bonding processes at low temperatures, activation of the wafer and chip surfaces is usually recommended. A plasma is usually applied to activate the wafer and chip surfaces in preparation for wafer-to-wafer (or wafer-to-chip) bonding at temperatures lower than 100° C. Wafer surface activation via a plasma reduces the processing temperature and increases the wafer bonding strength. The wafer bonding strength is increased due to the increased amount of Si—OH groups, removal of wafer surface-contaminants, enhancement of viscous flow of the surface layer and enhancement of the diffusivity of water and gas trapped at the interface. In particular, atmospheric pressure plasma activated bonding involves igniting a plasma without using a low pressure environment, while maintaining a low temperature.

In some applications, plasma treatment in different directions is needed. This can be accomplished by stacking two separate plasma heads with each plasma head having it's own control system so that they provide plasma sources directed in opposite directions. However, this is a space consuming and expensive arrangement. Accordingly, there is a need for a space saving and inexpensive plasma head that can treat wafers placed in opposite directions simultaneously.

### SUMMARY OF THE INVENTION

The present invention relates to a system and method for a double-sided atmospheric plasma head, and in particular to a double-sided atmospheric plasma source head that provides plasma gases directed in opposite directions.

In general, in one aspect the invention provides an atmospheric pressure plasma system including a double-sided atmospheric pressure plasma source that comprises a single plasma head that generates two collinear and opposite directed glow discharge-type plasmas. The single plasma head comprises a gas inlet, two separate collinear and opposite to each other internal process gas passages, a two-zone radio frequency (RF) electrode that generates two separate plasma gases in the two separate gas passages, and wherein the two separate plasma gases exit the plasma head through two separate and opposite to each other output slits, respectively.

Implementations of this aspect of the invention include one or more of the following. Each gas passage is surrounded by a dielectric liner. The plasma head further includes a ground electrode and each of the two-zone RF electrode and the ground electrode are arranged at opposite sides of an outer surface of a segment of each of the two gas passages, respectively. The double-sided plasma source comprises a back casing and a front casing that are attached to each other in an airtight way, and between the attached front and back casings a cavity is formed that is shaped and dimensioned to contain the plasma head. The plasma head includes a front plate, a back plate and the two-zone RF electrode that is contained within a cavity formed between the front plate and the back plate. The front and back plates comprise a dielectric material, and the dielectric material may be one of glass, quartz, sapphire, fused silica, strontium titanate, calcium copper titanate, mica, aluminum nitride, silicon nitride, or alumina. The front plate includes a gas inlet interfacing with two collinear vertically extending slot passages that terminate at the two separate and opposite to each other output slits, respectively. A process gas enters through the gas inlet and travels through the two vertically extending slot passages where it gets activated and then exits through the two separate and opposite to each other output slits. The two-zone RF electrode is dog-bone shaped and includes a top square shaped portion, a bottom square shaped portion and a narrow intermediary portion. The two-zone RF electrode comprises a front side that that generates the two separate plasma gases in the two separate gas passages, and a back side that comprises fins that function as a heat sink. The back plate of the plasma head functions as a cooling jacket and includes a cooling fluid inlet, and a cooling fluid outlet, and wherein a cooling fluid enters through the cooling fluid inlet and circulates through a back side of the two-zone RF electrode and then exits through the cooling fluid outlet. The gas inlet comprises a diffuser that generates laminar process gas flows in the two separate gas passages. The diffuser comprises a cylindrical body having a top flat surface, a bottom flat surface, a flat front surface, a flat back surface and semi-circular left and right surfaces and wherein the top surface includes a top horizontal channel cutout, and the bottom flat surface includes a bottom horizontal channel cutout and wherein small top openings are formed on a back surface of the top horizontal channel cutout, and small openings are formed on a back surface of the bottom horizontal channel cutout, and wherein the cylindrical body further comprises a top inner slot that communicates with the small top openings, and an bottom inner slot that communicates with the small bottom openings, and a central divider that separates the two internal process gas passages.

In general, in another aspect, the invention provides a method for generating an atmospheric pressure plasma including providing a double-sided atmospheric pressure plasma source that comprises a single plasma head and generating two collinear and opposite directed glow discharge-type plasmas. The single plasma head comprises a gas inlet, two separate collinear and opposite to each other internal process gas passages, a two-zone radio frequency (RF) electrode that generates two separate plasma gases in the two separate gas passages, and wherein the two separate plasma gases exit the plasma head through two separate and opposite to each other output slits, respectively.

In general, in another aspect, the invention provides a method for treating with an atmospheric plasma and activating two separate surfaces arranged in two opposite directions simultaneously, including the following. First, providing a double-sided atmospheric pressure plasma source that comprises a single plasma head and generating two collinear and opposite directed glow discharge-type plasmas, wherein the single plasma head comprises a gas inlet, two separate collinear and opposite to each other internal process gas passages, a two-zone radio frequency (RF) electrode that generates two separate plasma gases in the two separate gas passages, and wherein the two separate plasma gases exit the plasma head through two separate and opposite to each other output slits, respectively. Next, aligning a first bonding surface of a first chip and a first bonding surface of a wafer. Next, inserting the double-sided atmospheric plasma source into a space between the aligned first bonding surfaces of the first chip and the wafer. Next, activating simultaneously the first bonding surfaces of the first chip and the wafer with the two collinear and opposite directed glow discharge-type plasmas of the double-sided atmospheric plasma source. Next, removing the double-sided atmospheric plasma source, and then bonding the activated and aligned first bonding surfaces of the first chip and the first wafer. The method may further include aligning a first surface of a second chip and a second surface of the first chip that is opposite to the first surface, then inserting the double-sided atmospheric plasma source in a space between the first surface of the second chip and the second surface of the first chip, then activating simultaneously the aligned first surface of the second chip and the second surface of the first chip, then removing the double-sided atmospheric plasma source, and then bonding the aligned and activated first surface of the second chip and the second surface of the first chip are bonded. The process steps are repeated with (n) additional chips until a n-stacked chip configuration is achieved.

The details of one or more embodiments of the invention are set forth in the accompanying drawings and description below. Other features, objects and advantages of the invention will be apparent from the following description of the preferred embodiments, the drawings and from the claims.

### BRIEF DESCRIPTION OF THE DRAWINGS

Referring to the figures, wherein like numerals represent like parts throughout the several views:

FIG. 1 depicts a schematic diagram of a prior art single-sided plasma head of an atmospheric pressure plasma system;

FIG. 2A is a top perspective view of double-sided atmospheric plasma head, according to this invention;

FIG. 2B is a bottom perspective view of the double-sided atmospheric plasma head of FIG. 2A;

FIG. 3A is an exploded front perspective view of the double-sided atmospheric plasma head of FIG. 2A ;

FIG. 3B is an exploded back perspective view of the double-sided atmospheric plasma head of FIG. 2A ;

FIG. 4A is a front perspective view of the plasma cell located within the double-sided atmospheric plasma head of FIG. 2A ;

FIG. 4B is a back perspective view of the plasma cell of FIG. 4A ;

FIG. 5 is an exploded back perspective view of the plasma cell of FIG. 4A;

FIG. 6A is a front perspective view of the two zone RF electrode of the plasma cell of FIG. 4A;

FIG. 6B is a back perspective view of the two zone RF electrode of FIG. 6A;

FIG. 7 depicts a vertical cross-sectional view of the plasma cell of FIG. 4A, along an AA′ plane;

FIG. 8 depicts a vertical cross-sectional perspective view of the plasma cell of FIG. 4A, along the AA′ plane;

FIG. 9 depicts a horizontal cross-sectional perspective view of the plasma cell of FIG. 4A, along a BB′ plane;

FIG. 10 depicts the cooling gas flow through the plasma cell of FIG. 4A;

FIG. 11A-FIG. 11D depict schematically the process steps of using the double-sided atmospheric plasma head of FIG. 2A for treating chip and wafer surfaces in two opposite directions simultaneously;

FIG. 12A-FIG. 12B is a flow diagram of the process of using the double-sided atmospheric plasma head of FIG. 2A for treating chip and wafer surfaces in two opposite directions simultaneously;

FIG. 13A is a top front perspective view of another embodiment of the double-sided atmospheric plasma head, according to this invention;

FIG. 13B is a top back perspective view of the double-sided atmospheric plasma headof FIG. 13A;

FIG. 14 is an exploded back perspective view of the double-sided atmospheric plasma head of FIG. 13A;

FIG. 15 depicts a vertical cross-sectional perspective view of the double-sided atmospheric plasma head of FIG. 13A;

FIG. 16 is a front perspective view of the plasma cell located within the double-sided atmospheric plasma head of FIG. 13A;

FIG. 17 is vertical cross-sectional perspective view of the plasma cell of FIG. 16;

FIG. 18 is a front perspective view of the gas inlet assembly (diffuser) of plasma cell of FIG. 16;

FIG. 19 is a velocity profile of the gas flow through a plasma cell without the diffuser of FIG. 18;

FIG. 20 is a velocity profile of the gas flow through a plasma cell with the diffuser of FIG. 18; and

FIG. 21 is a photograph of the double-sided atmospheric plasma head of FIG. 13A.

### DETAILED DESCRIPTION OF THE INVENTION

The present invention relates to a system and method for a double-sided atmospheric plasma head, and in particular to a double-sided atmospheric plasma source head that provides plasma gases directed in opposite directions.

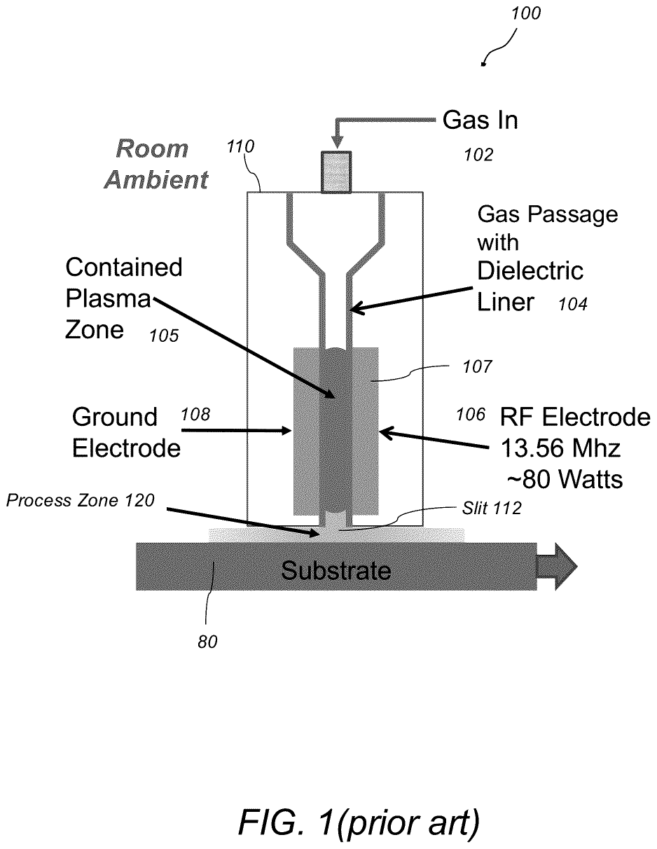

Referring to FIG. 1, a prior art atmospheric pressure plasma source 100 is used to activate a top surface of a substrate 80. Substrates with diameters from 2 mm up to 300 mm are supported on a computer controlled X-Y-Z stage. The plasma source 100 ignites a plasma at specific local areas or the top surface of the substrate. An example of an atmospheric pressure plasma system for surface preparation is the Ontos 7, manufactured by Setna Corporation LLC, Chester, NH 03036, USA, incorporated herein by reference.

Referring to FIG. 1, the atmospheric plasma source 100 includes an enclosure 110, a gas inlet 102, a gas passage with a dielectric liner 104, an RF electrode 106, and a ground electrode 108. RF electrode 106 and ground electrode 108 are arranged at opposite sides of a segment 107 of the gas passage 104. Gas enters the passage with the dielectric liner 104 through inlet 102 and passes through segment 107. Between the two electrodes 106, 108 in segment 107, a glow discharge-type plasma is generated by applying alternating voltage to the RF electrode. The plasma is completely contained within the source head 100. The plasma exits the gas passage via a slit 112 and enters a process zone area 120 immediately above the top surface of the substrate 80. Laminar flow of the plasma gas in the process zone 120 excludes the atmosphere from the process zone 120 and thus vacuum is not needed. The activated plasma gas in the process zone 120 is a cool gas with a temperature lower than 100° C. and does not include ions or hot electrons. In one example, the electrodes are driven via RF power of 120W at 13.56 MHz. Four mass flow channels deliver precise digital control of a non-toxic gas mix to the plasma head. Examples of gases used include Helium, Nitrogen, Oxygen, forming gas, and other gas mixtures, among others. The electrodes 106, 108 and the gas passage 104 are contained within the enclosure 110. In one example, the plasma output slit 112 has a length from 10 mm to 40 mm.

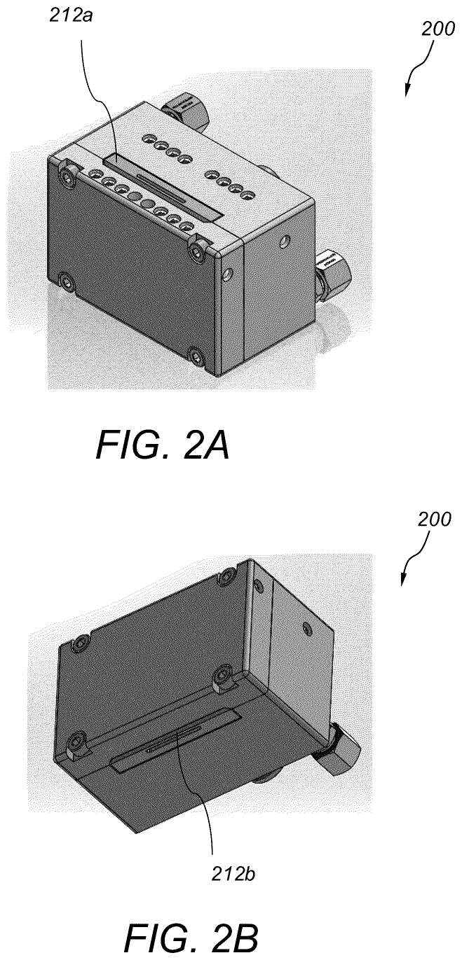

Referring to FIG. 2A, and FIG. 2B, a double-sided (bidirectional) atmospheric plasma head 200 according to this invention includes a single plasma source that has two separate collinear internal process gas paths and two separate RF zones that generate two separate plasma gases that exit the plasma head through two separate output slits 212a and 212b. The two separate collinear gas paths and the two separate RF zones are coupled to the same single source, thus enabling a single control system to operate the two opposite directed plasmas simultaneously.

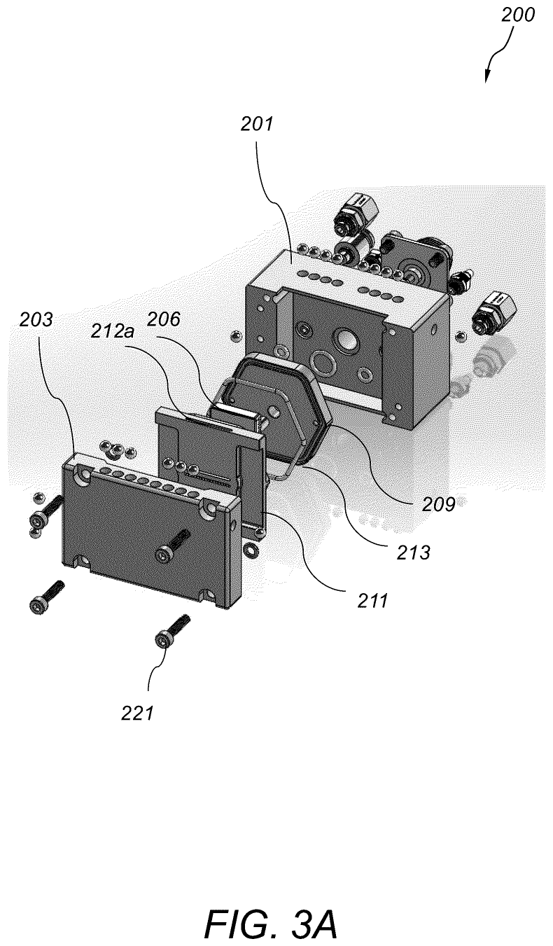

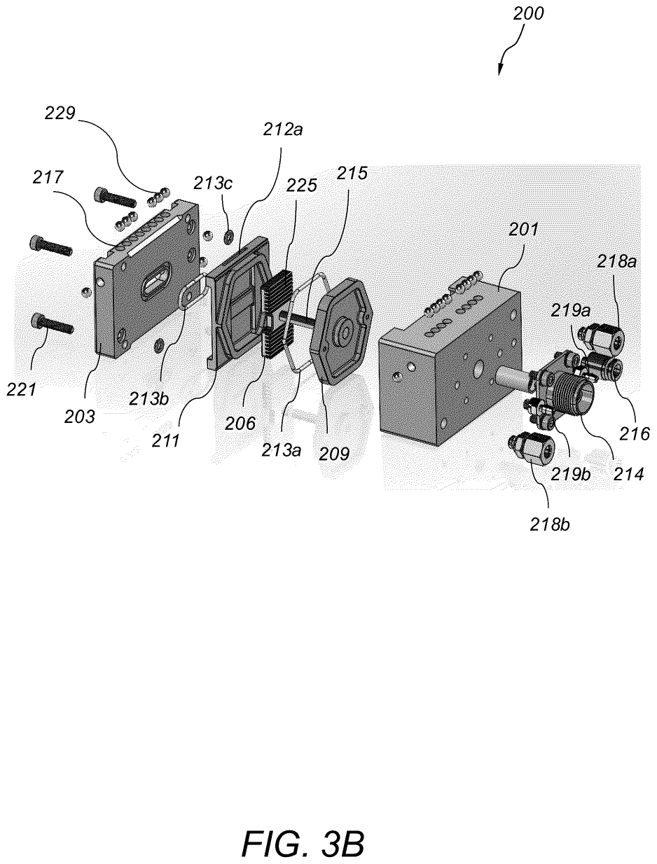

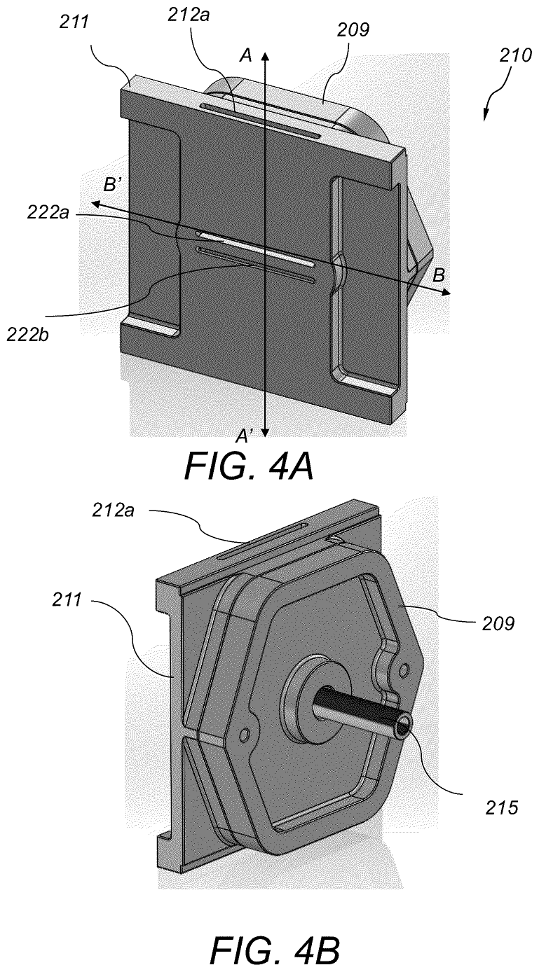

Referring to FIG. 3A and FIG. 3B, the double-sided atmospheric plasma head 200 includes a back casing 201 and a front casing 203 that are attached to each other in an airtight way with screws 221. Between the front and back casings 203, 201 a cavity is formed that is shaped and dimensioned to contain the plasma cell 210, shown assembled in FIG. 4A and FIG. 4B. In one example, casings 201, 203 are made of aluminum. In other examples, casings 201, 203, are made of stainless steel, metallic alloys, ceramics or intermetallic compounds, among others. The RF power is applied to the plasma cell via an RF connector 214, the process gas is supplied via a gas inlet connector 216, a cooling gas enters the casing via inlet connector 219a and exits via outlet connector 219b, and cooling water enters via inlet 218a and exits via outlet 218b. The cooling gas may be nitrogen, clean dry air (CDA) or CO2. In one example, the double-sided atmospheric plasma head 200 has a length of 80 mm, height of 50 mm and width of 45 mm.

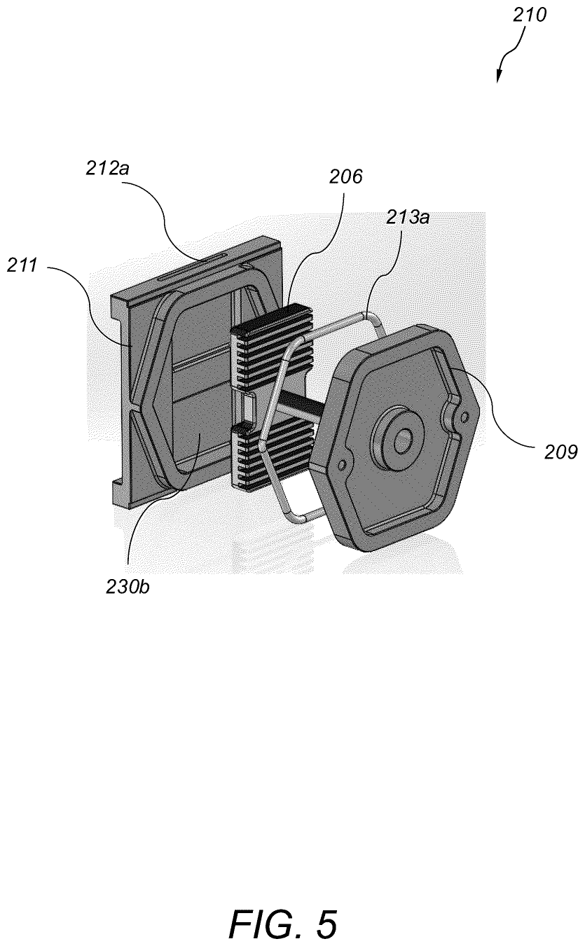

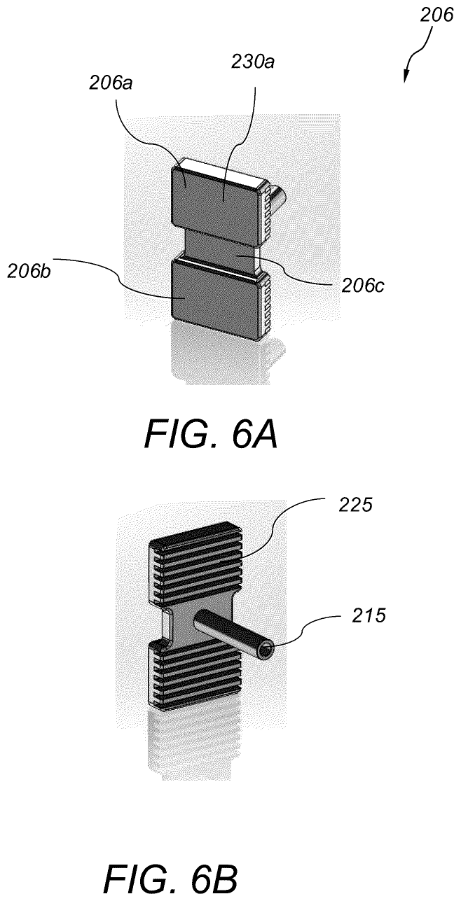

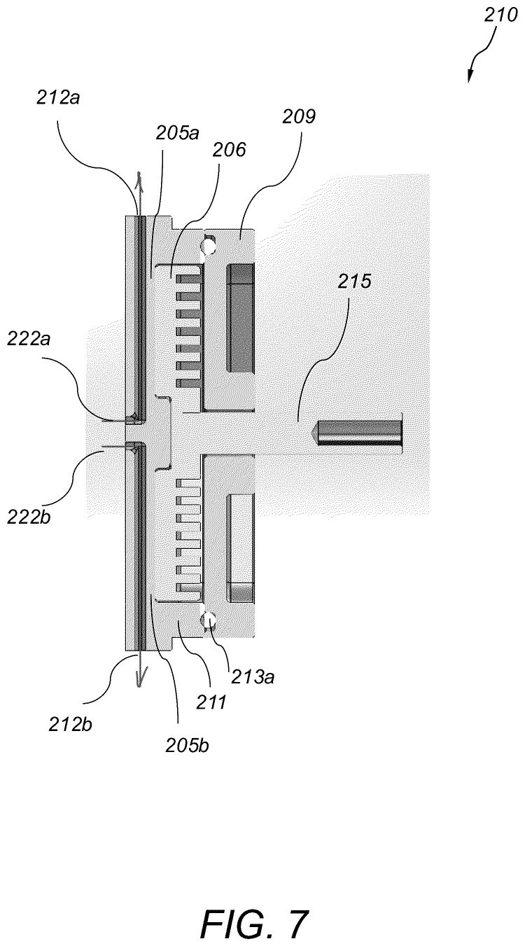

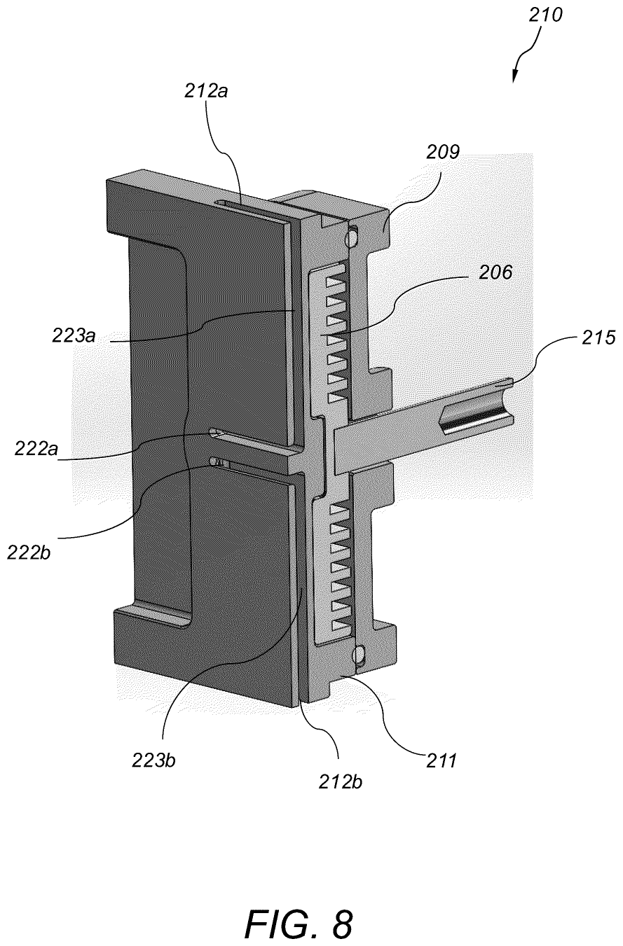

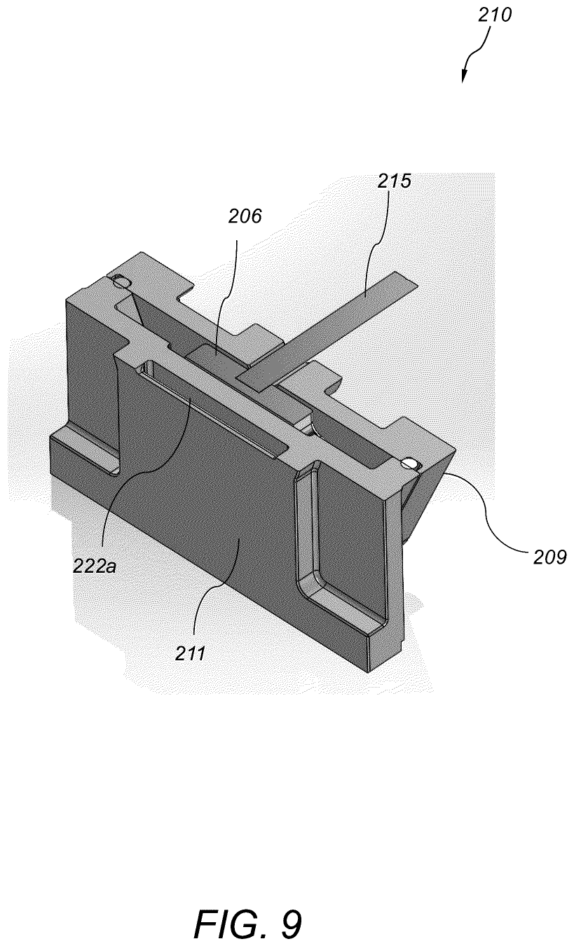

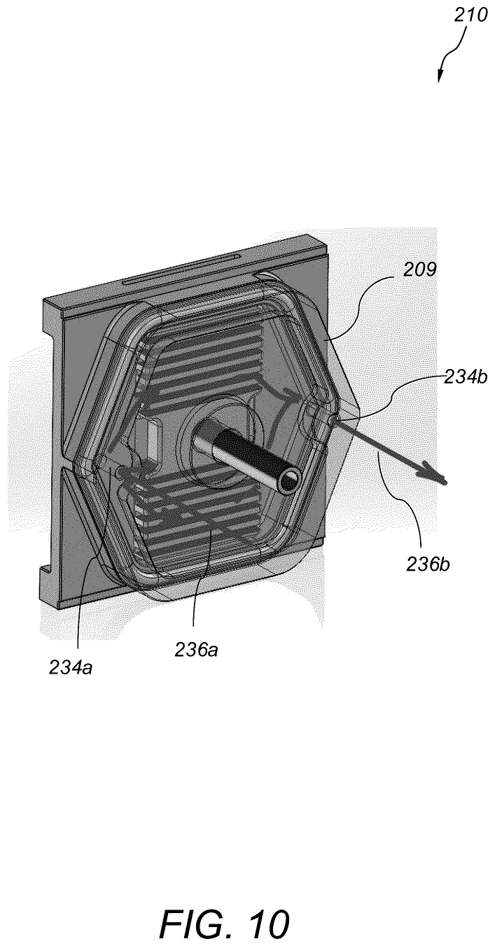

Referring to FIG. 4A, FIG. 4B and FIG. 5, plasma cell 210 includes a front plate 211, a back plate 209 and a two zone RF electrode 206 contained within a cavity formed between the front plate 211 and back plate 209. An O-ring 213a is placed between the front and back plates 211, 209 to seal the electrode, to prevent the cooling gas from entering the plasma areas, and to prevent the process gas from entering the electrode pocket creating unwanted plasma in that area. RF electrode 206 receives power through an elongated rod contact 215 that passes through an opening of the back plate 209, through an opening of the back casing and interfaces with the RF connector 214. Front and back plates 211 and 209 are made of a dielectric material or are coated with a dielectric material 230b. The dielectric material may be glass, quartz, sapphire, fused silica, strontium titanate, calcium copper titanate, mica, aluminum nitride, silicon nitride, alumina, or other ceramic materials, among others. Plates 209, 211 may be machined or 3D-printed. Front plate 211 includes two horizontal gas inlet slits 222a, 222b interfacing with a vertically extending slot passage that terminates at the top plasma output slit 212a and at the bottom plasma output slit 212b, as shown in FIG. 8. The process gas enters through inlet slits 222a, 222b and travels through the vertically extending slot passage where it gets activated and the then exits through the top plasma output slit 212a and the bottom plasma output slit 212b, as shown in FIG. 7-FIG. 9. In other embodiments, the gas inlet openings 222a, 222b include a group of small hole openings or small horizontal or vertical slit openings or any other geometry needed to generate the desired gas flow characteristics. Two zone RF electrode 206 is dog-bone shaped and includes a top square shaped portion 206a, a bottom square shaped portion 206b and a narrow intermediary portion 206c, as shown in FIG. 6A. The top and bottom portions 206a, 206b of the back side of the RF electrode 206 includes machined fins 225 that function as a heat sink, as shown in FIG. 6B. The front side of the top and bottom portions 206a, 206b form the active plasma areas. The back plate 209 of the plasma cell functions as a cooling jacket and includes a cooling gas inlet 234a, and a cooling gas outlet 234b, through which the cooling gas enters and circulates through the back side of the RF electrode 206, as shown in FIG. 10.

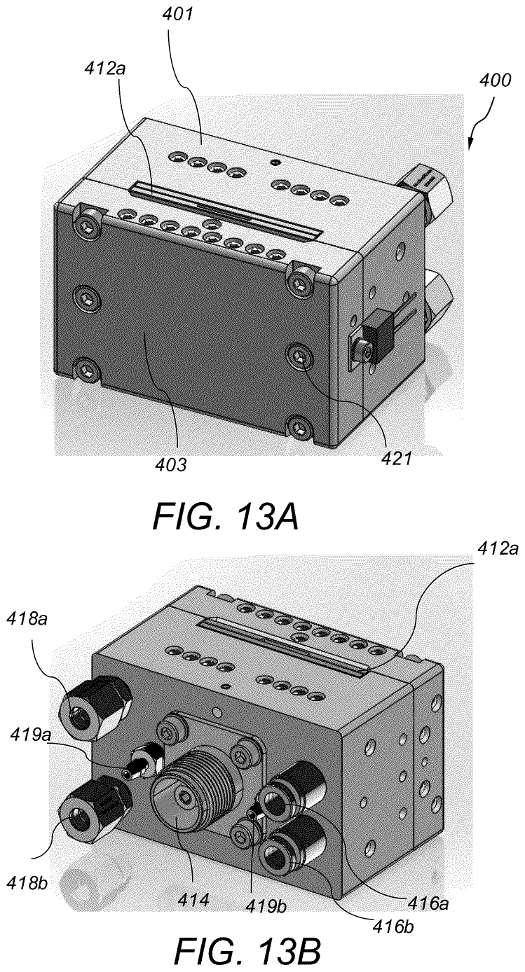

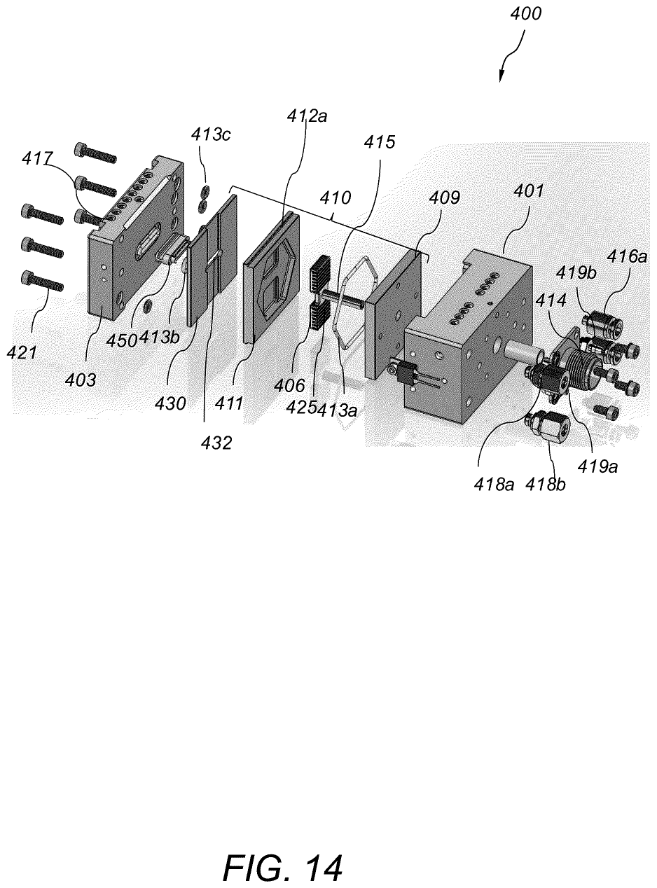

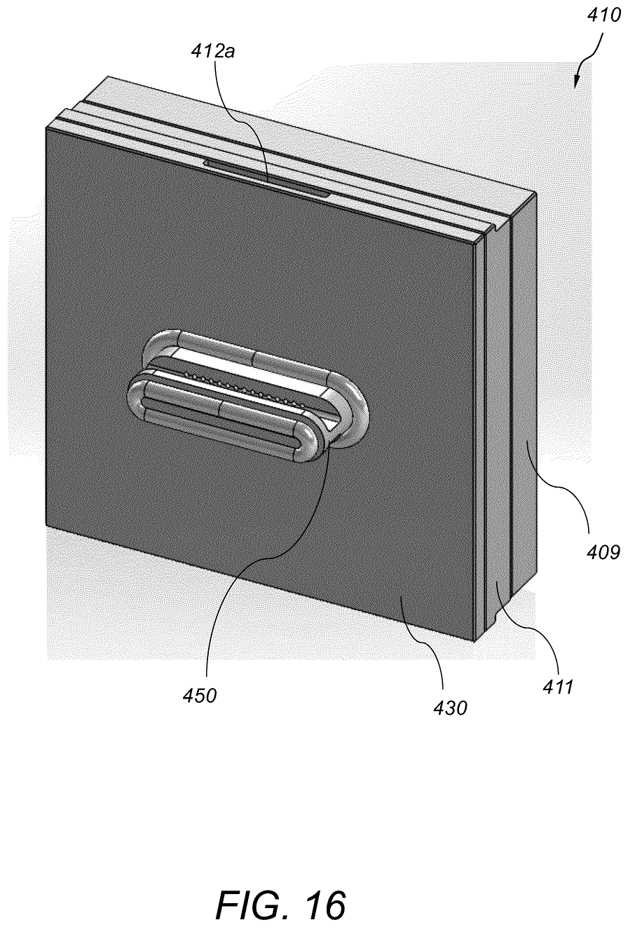

Referring to FIG. 13A and FIG. 13B, in another embodiment, the double-sided atmospheric plasma head 400 includes a back casing 401 and a front casing 403 that are attached to each other in an airtight way with screws 421. Between the front and back casings 403, 401 a cavity is formed that is shaped and dimensioned to contain the plasma cell 410, shown assembled in FIG. 16 and disassembled in FIG. 14. The RF power is applied to the plasma cell via an RF connector 414, the process gas is supplied via a gas inlet connector 416a, a cooling gas enters the casing via inlet connector 419a and exits via outlet connector 419b, and cooling water enters via inlet 418a and exits via outlet 418b. The cooling gas may be nitrogen, clean dry air (CDA) or CO2.

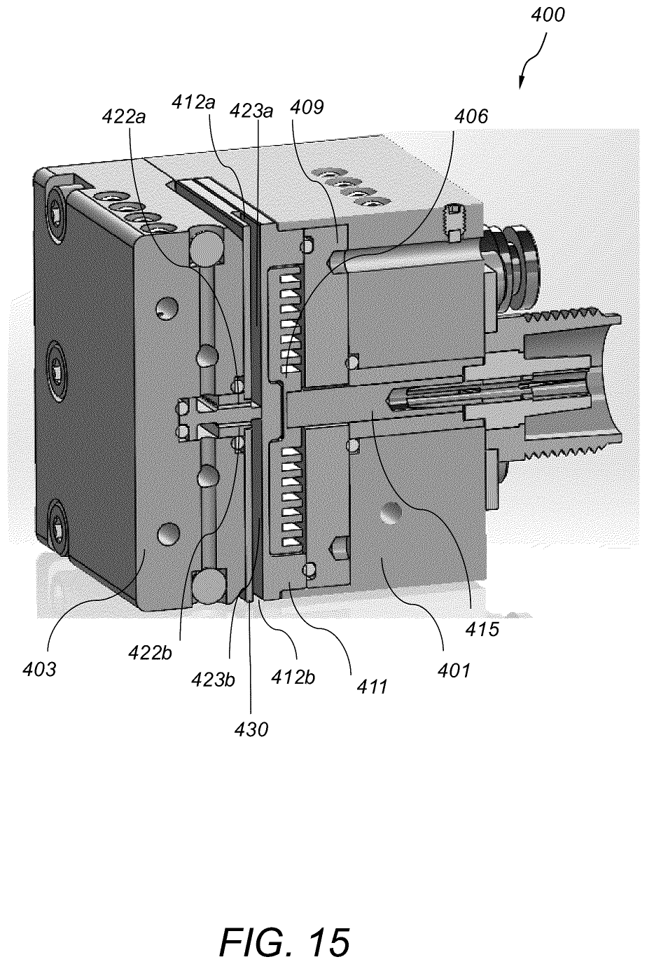

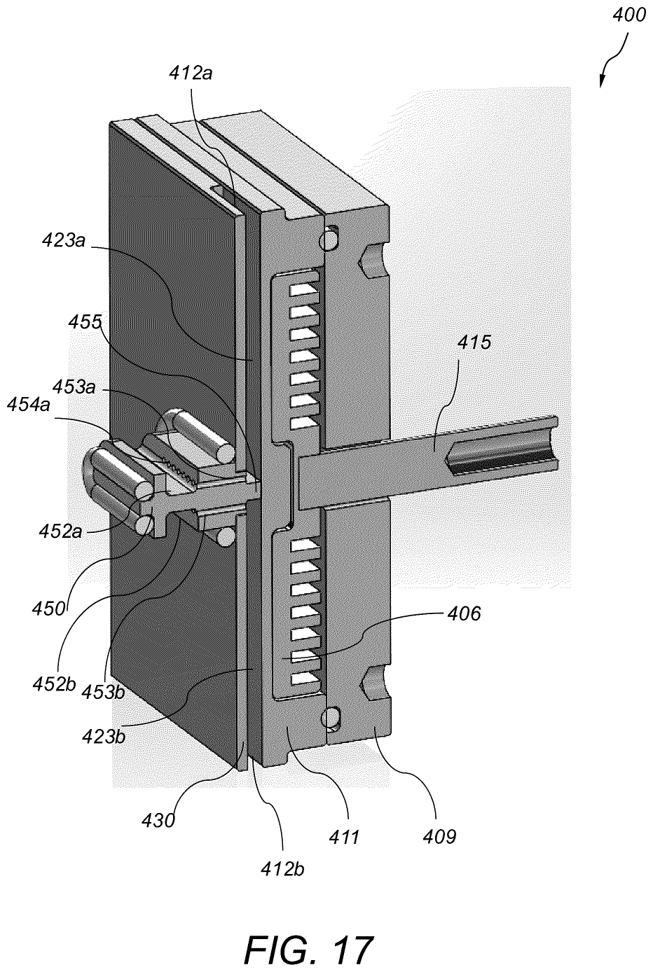

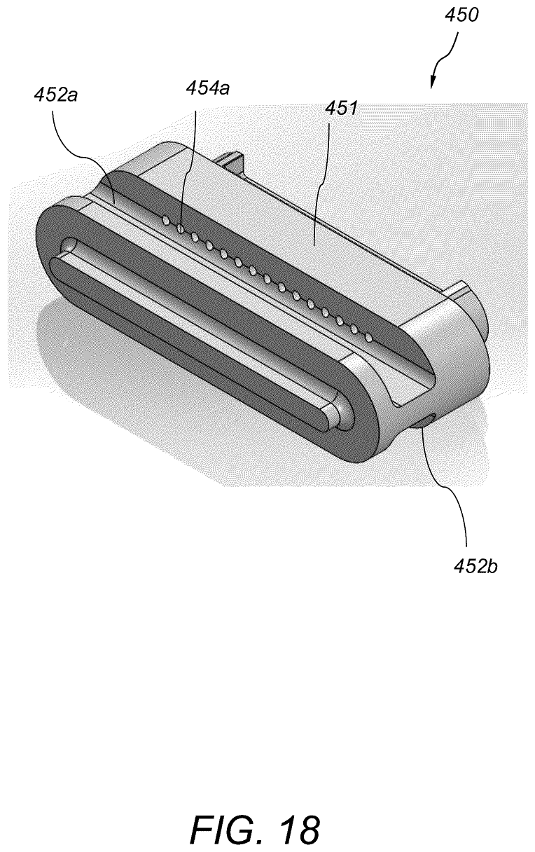

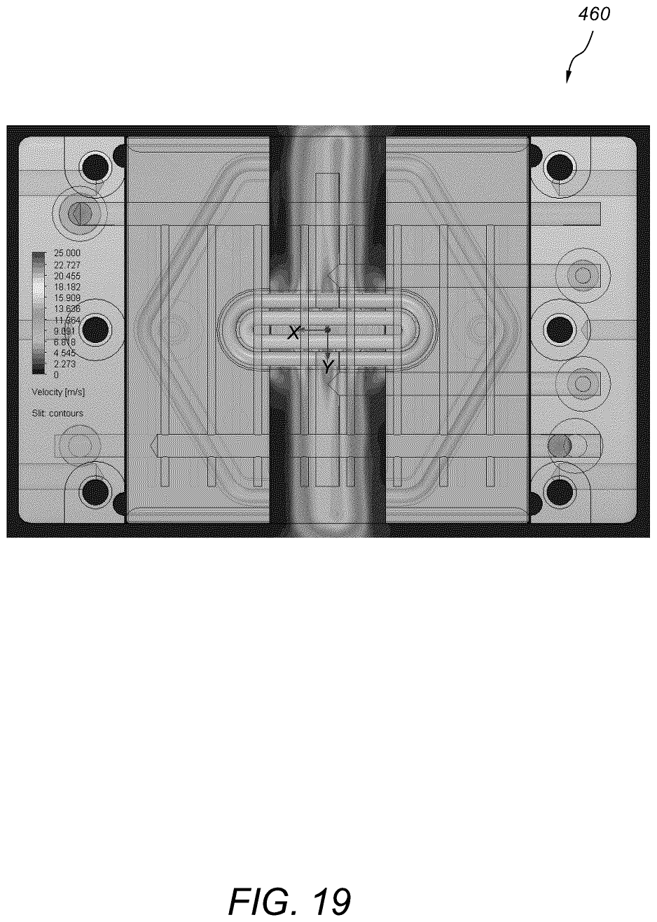

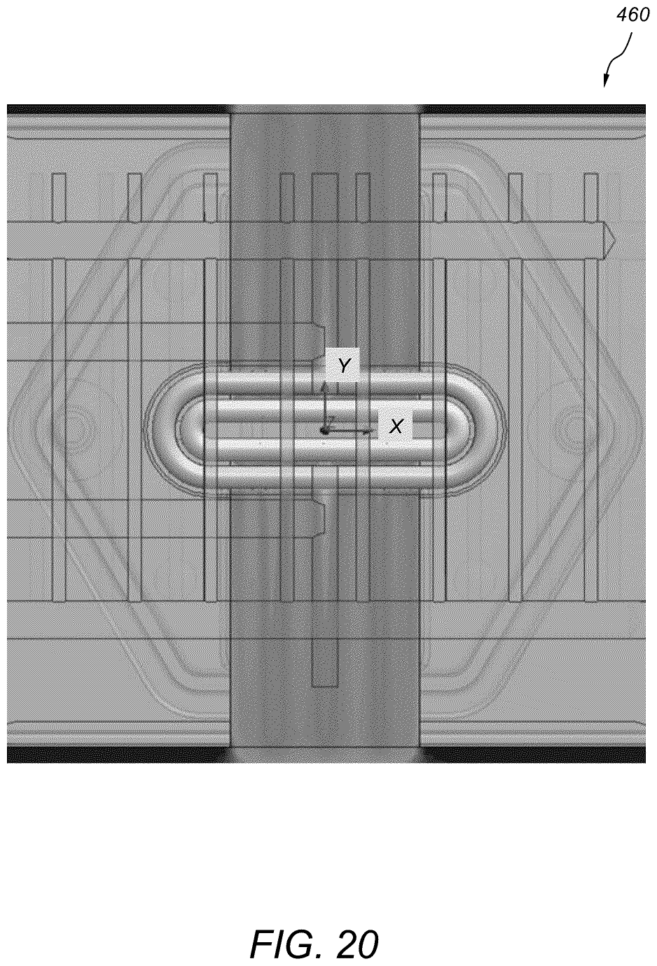

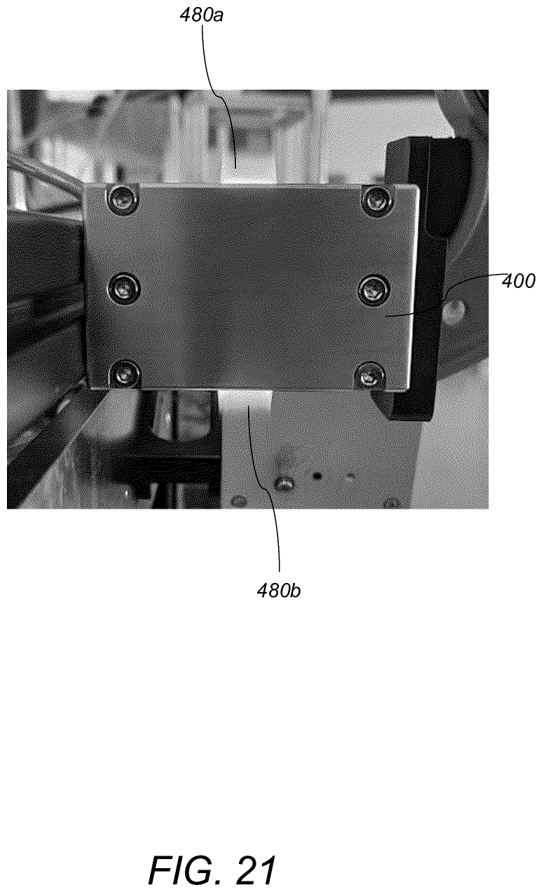

Referring to FIG. 14, FIG. 15, FIG. 16, FIG. 17, and FIG. 18, plasma cell 410 includes a front plate 411, a back plate 409 and a two zone RF electrode 406 contained within a cavity formed between the back surface of the front plate 411 and front surface of the back plate 409. An O-ring 413a is placed between the front and back plates 411, 409 to seal the electrode, to prevent the cooling gas from entering the plasma areas, and to prevent the process gas from entering the electrode pocket creating unwanted plasma in that area. In this embodiment the plasma cell 410 includes a plate 430 placed adjacent to the front surface of the front plate 411. Plate 430 includes a horizontal slot opening 432 that receives a gas inlet assembly (diffuser) 450. Gas inlet assembly 450 functions as a flow diffuser that optimizes the laminarity of the process gas flow through the plasma cell. Gas inlet assembly 450 includes a cylindrical diffuser body 451 having a top flat surface, a bottom flat surface and semi-circular left and right surfaces. The top surface includes a top horizontal channel cutout 452a, and the bottom flat surface includes a bottom horizontal channel cutout 452b. Small top openings 454a are formed on the back surface of channel cutout 452a, and small openings 454b are formed on the back surface of channel cutout 452b (not shown). The diffuser body 451 further includes a top inner slot 453a that communicates with the small top openings 454a and the top gas passage area 423a, and a inner bottom slot 453b that communicates with the small bottom openings 454b and the bottom gas passage area 423b, and a central divider 455 that is inserted into the slot opening 432 and divides the top and bottom gas passage areas 423a, 423b, as shown in FIG. 18. The gas enters into the top and bottom horizontal channel cutouts 452a, 452b and enters the top and bottom gas passage areas 423a, 423b, via the small top and bottom openings 454a, 454b and top and bottom slots 453a, 453b, respectively. The process gas that enters the top and bottom gas passage areas 423a, 423b gets activated and then exits through the top plasma output slit 412a and the bottom plasma output slit 412b, as shown in FIG. 17. FIG. 19 depicts a velocity profile of the gas flow through the plasma cell without the gas inlet assembly 450 and FIG. 20 depicts a velocity profile of the gas flow through the plasma cell with the gas inlet assembly 450. We observe that the diffuser 450 provides homogeneous and laminar gas flows through the gas passage areas 423a, 423b. RF electrode 406 receives power through an elongated rod contact 415 that passes through an opening of the back plate 409, through an opening of the back casing and interfaces with the RF connector 414. Front and back plates 411 and 409 are made of a dielectric material or are coated with a dielectric material. The dielectric material may be glass, quartz, sapphire, fused silica, strontium titanate, calcium copper titanate, mica, aluminum nitride, silicon nitride, alumina, or other ceramic materials, among others. Plates 409, 411 and 430 may be machined or 3D-printed. In other embodiments the diffuser structure 450 is formed directly in the structure of the plate 430.

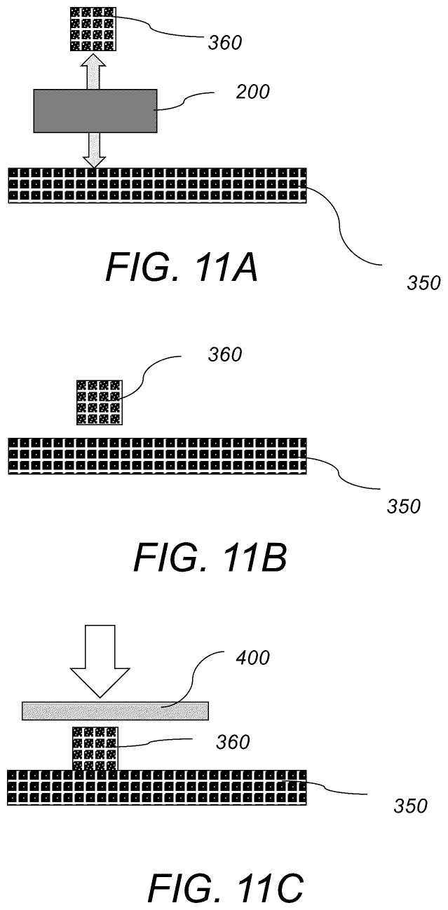

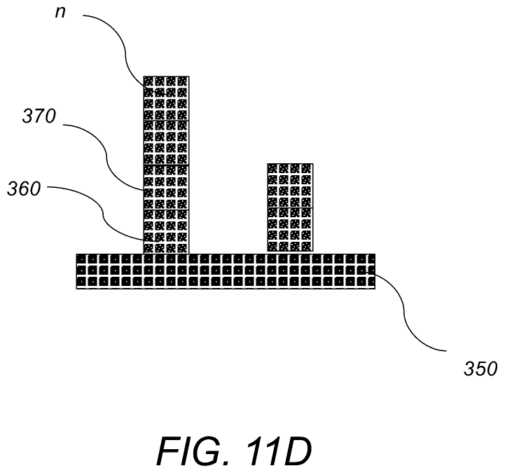

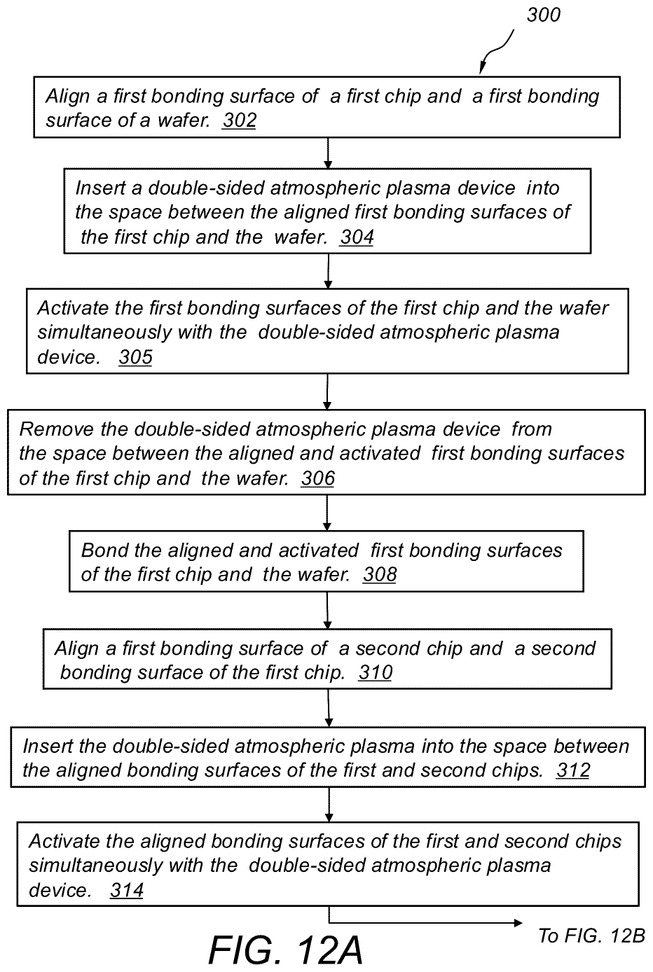

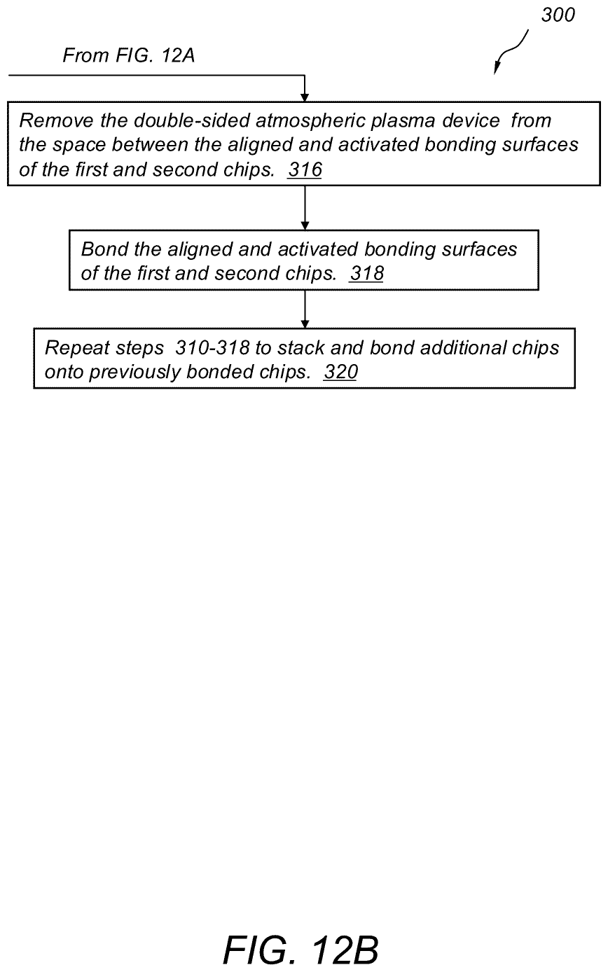

As was mentioned above, the double-sided atmospheric plasma head 200 is used for treating with an atmospheric plasma and activating surfaces in two opposite directions simultaneously. Referring to FIG. 11A-FIG. 11D and FIG. 12A-FIG. 12B, the process 300 of using the double-sided atmospheric plasma head 200 for chip-to-wafer bonding includes the following. First, a first bonding surface of a first chip 360 and a first bonding surface of a wafer 350 are aligned (301). Next, the double-sided atmospheric plasma head 200 is inserted into the space between the aligned first bonding surfaces of the first chip 360 and the wafer 350 (304), as shown in FIG. 11A. Next, the first bonding surfaces of the first chip 360 and the wafer 350 are simultaneously activated with the top and bottom exiting plasmas of the double-sided atmospheric plasma head 200 (305). Next, the double-sided atmospheric plasma head 200 is removed (306) and the activated and aligned first bonding surfaces of the first chip 360 and the first wafer 350 are bonded (308), as shown in FIG. 11B and FIG. 11C, respectively. The process is repeated to bond a second chip 370 on top of the first chip 360, by aligning a first surface of a second chip and a second surface of the first chip (opposite to the first surface) (310). Next, the double-sided atmospheric plasma head 200 is inserted in the space between the first surface of the second chip 370 and the second surface of the first chip 360 (312) and then the aligned first surface of the second chip and the second surface of the first chip are activated (314). Next, the double-sided atmospheric plasma head 200 is removed (316) and the aligned and activated first surface of the second chip and the second surface of the first chip are bonded (318). The process is repeated with additional chips (n) until a stacked chip configuration is achieved (320), as shown in FIG. 11D.

Several embodiments of the present invention have been described. Nevertheless, it will be understood that various modifications may be made without departing from the spirit and scope of the invention. Accordingly, other embodiments are within the scope of the following claims.

What is claimed is:

1. An atmospheric pressure plasma system comprising:
a double-sided atmospheric pressure plasma source that comprises a single plasma head that generates two collinear and opposite directed glow discharge-type plasmas;
wherein the single plasma head comprises a gas inlet, two separate collinear and opposite to each other internal process gas passages, a two-zone radio frequency (RF) electrode that generates two separate plasma gases in the two separate gas passages, and wherein the two separate plasma gases exit the plasma head through two separate and opposite to each other output slits, respectively.

2. The system of claim 1, wherein each gas passage is surrounded by a dielectric liner.

3. The system of claim 1, wherein the plasma head further comprises a ground electrode and wherein each of the two-zone RF electrode and the ground electrode are arranged at opposite sides of an outer surface of a segment of each of the two gas passages, respectively.

4. The system of claim 1, wherein the double-sided plasma source comprises a back casing and a front casing that are attached to each other in an airtight way, and wherein between the attached front and back casings a cavity is formed that is shaped and dimensioned to contain the plasma head.

5. The system of claim 1, wherein the plasma head comprises a front plate, a back plate and the two-zone RF electrode that is contained within a cavity formed between the front plate and the back plate.

6. The system of claim 5, wherein the front and back plates comprise a dielectric material, and wherein the dielectric material comprises one of glass, quartz, sapphire, fused silica, strontium titanate, calcium copper titanate, mica, aluminum nitride, silicon nitride, or alumina.

7. The system of claim 5, wherein the front plate includes a gas inlet interfacing with two collinear vertically extending slot passages that terminate at the two separate and opposite to each other output slits, respectively, and wherein a process gas enters through the gas inlet and travels through the two vertically extending slot passages where it gets activated and then exits through the two separate and opposite to each other output slits.

8. The system of claim 1, wherein the two-zone RF electrode is dog-bone shaped and includes a top square shaped portion, a bottom square shaped portion and a narrow intermediary portion.

9. The system of claim 1, wherein the two-zone RF electrode comprises a front side that that generates the two separate plasma gases in the two separate gas passages, and a back side that comprises fins that function as a heat sink.

10. The system of claim 5, wherein the back plate of the plasma head functions as a cooling jacket and includes a cooling fluid inlet, and a cooling fluid outlet, and wherein a cooling fluid enters through the cooling fluid inlet and circulates through a back side of the two-zone RF electrode and then exits through the cooling fluid outlet.

11. The system of claim 1, wherein the gas inlet comprises a diffuser that generates laminar process gas flows in the two separate gas passages.

12. The system of claim 11, wherein the diffuser comprises a cylindrical body having a top flat surface, a bottom flat surface, a flat front surface, a flat back surface and semi-circular left and right surfaces and wherein the top surface includes a top horizontal channel cutout, and the bottom flat surface includes a bottom horizontal channel cutout and wherein small top openings are formed on a back surface of the top horizontal channel cutout, and small openings are formed on a back surface of the bottom horizontal channel cutout, and wherein the cylindrical body further comprises a top inner slot that communicates with the small top openings, and an bottom inner slot that communicates with the small bottom openings, and a central divider that separates the two internal process gas passages.

13. A method for generating an atmospheric pressure plasma comprising:
providing a double-sided atmospheric pressure plasma source that comprises a single plasma head and generating two collinear and opposite directed glow discharge-type plasmas;
wherein the single plasma head comprises a gas inlet, two separate collinear and opposite to each other internal process gas passages, a two-zone radio frequency (RF) electrode that generates two separate plasma gases in the two separate gas passages, and wherein the two separate plasma gases exit the plasma head through two separate and opposite to each other output slits, respectively.

14. A method for treating with an atmospheric plasma and activating two separate surfaces arranged in two opposite directions simultaneously, comprising:
providing a double-sided atmospheric pressure plasma source that comprises a single plasma head and generating two collinear and opposite directed glow discharge-type plasmas, wherein the single plasma head comprises a gas inlet, two separate collinear and opposite to each other internal process gas passages, a two-zone radio frequency (RF) electrode that generates two separate plasma gases in the two separate gas passages, and wherein the two separate plasma gases exit the plasma head through two separate and opposite to each other output slits, respectively;
aligning a first bonding surface of a first chip and a first bonding surface of a wafer;
inserting the double-sided atmospheric plasma source into a space between the aligned first bonding surfaces of the first chip and the wafer;
activating simultaneously the first bonding surfaces of the first chip and the wafer with the two collinear and opposite directed glow discharge-type plasmas of the double-sided atmospheric plasma source;
removing the double-sided atmospheric plasma source; and
bonding the activated and aligned first bonding surfaces of the first chip and the first wafer.

15. The method of claim 14, further comprising:
aligning a first surface of a second chip and a second surface of the first chip that is opposite to the first surface;
inserting the double-sided atmospheric plasma source in a space between the first surface of the second chip and the second surface of the first chip;
activating simultaneously the aligned first surface of the second chip and the second surface of the first chip;
removing the double-sided atmospheric plasma source; and
bonding the aligned and activated first surface of the second chip and the second surface of the first chip are bonded.

16. The method of claim 14, further comprising repeating the steps of claim 14 with (n) additional chips until a n-stacked chip configuration is achieved.
